(19) United States
(12) Patent Application Publication
(10) Pub. No.: US 2018/0053485 A1
(43) Pub. Date: Feb. 22, 2018

(54) DISPLAY PANEL DRIVING METHOD AND DISPLAY PANEL DRIVING DEVICE

(71) Applicant: SHENZHEN CHINA STAR OPTOELECTRONICS TECHNOLOGY CO., LTD., GUANGDONG (CN)

(72) Inventor: Xiaohui YAO, GUANGDONG (CN)

(21) Appl. No.: 15/308,633

(22) PCT Filed: Jul. 1, 2016
(86) PCT No.: PCT/CN2016/088149

§ 371 Date: Nov. 3, 2016

(51) Int. Cl. G09G 3/36; H01L 27/12

(52) U.S. Cl. CPC G09G 3/3685; G09G 3/3674; G09G 2310/0278; G09G 2310/061; H01L 27/1214

(57) ABSTRACT

The present invention provides a display panel driving device and a display panel driving method, which comprises: generating a scan driving voltage and transmitting the same to each scan line of the display panel to turn on each thin-film transistor of the display panel during a vertical blanking interval; setting a data driving voltage based on the voltage on a common electrode; and transmitting the data driving voltage to each pixel electrode of pixel units of the display panel.

### TECHNICAL FIELD OF THE DISCLOSURE

The present invention relates to liquid crystal display technology, and more particularly, to a display panel driving method and a display panel driving device.

### BACKGROUND OF THE DISCLOSURE

Liquid crystal display devices have advantages including lightweight, low power consumption, and low heat production such that liquid crystal display devices emerge from various types of display devices and widely used in iraodern information apparatus such as computers, mobile phones, and personal digital assistants, for example.

In the existing skills, all the thin-film transistors on a display panel are in a turned-off state during a vertical blanking interval such that a data driving voltage cannot be transmitted to pixel electrodes of pixel units of the display panel via the transistors, and therefore a voltage difference is existing between the pixel electrode and a common electrode during each vertical blanking interval. As a plenty of screen images alternate, residual ions gradually move toward the pixel electrode or the common electrode. As a result, a phenomenon of residual direct current occurs and residual screen images is appeared on the display panel.

### SUMMARY OF THE DISCLOSURE

The present invention provides a display panel driving method and a display panel driving device, Which can effectively solve the technical problem raised in the existing skills. The technical problem are described below. A voltage difference is existing between the pixel electrode and the coni mon electrode during each vertical blanking interval. As a plenty of screen images alternate, residual ions gradually move toward the pixel electrode or the common electrode. As a result, a phenomenon of residual direct current occurs and residual screen images is appeared on the display panel.

To solve above technical problem, the display panel driving method. provided in the present invention comprises: generating a scan driving voltage and transmitting the same to each scan line of the display panel to turn on each thin-film transistor of the display panel during a vertical blanking interval; setting a data driving voltage based on the voltage on a common electrode, in which the data driving voltage is set as the voltage of the common electrode and the voltage of the common electrode is constant; and transmitting the data driving voltage to each pixel electrode of pixel units of the display panel.

In the display panel driving method of the present invention, the data driving voltage is set to a first driving voltage during a (2n+1)th vertical blanking interval, the data driving voltage is set to a second driving voltage during a (2n)th vertical blanking interval, the first driving voltage is greater than the voltage of the common electrode, and the second driving voltage is less than the voltage of the common electrode.

In the display panel driving method of the present invention, the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

In the display panel driving method of the present invention, the data driving voltage is set to a first driving voltage during a (2n)th vertical blanking interval, the data driving voltage is set to a second driving voltage during a (2n+1)th vertical blanking interval, the first driving voltage is greater than the voltage of the common electrode, and the second driving voltage is less than the voltage of the common electrode.

In the display panel driving method of the present invention, the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

The present invention further provides a display panel driving method, which comprises: generating, a scan driving voltage and transmitting the sage to each scan line of the display panel to turn on each thin-film transistor of the display panel during a vertical blanking interval; setting a data driving voltage based on the voltage on a common electrode; and transmitting the data driving voltage to each pixel electrode of pixel units of the display panel.

In the display panel driving method of the present invention, the data driving voltage generating module sets the data driving voltage as the voltage of the common electrode.

In the display panel driving method of the present invention, the data driving voltage is set to a first driving voltage during a (2n+1)th vertical blanking interval, the data driving voltage is set to a second driving voltage during a (2n)th vertical blanking interval, the first driving voltage is greater than the voltage of the common electrode, and the second driving voltage is less than the voltage of the common electrode.

In the display panel driving method of the present invention, the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

In the display panel driving method of the present invention, the voltage of the common electrode is constant.

The present invention further provides a display panel driving device, which comprises: a scan driving voltage generating module configured for generating a. scan driving voltage and transmitting the same to each scan line of the display panel to turn on each thin-film transistor of the display panel during a vertical blanking interval; a data driving voltage generating module configured for setting a data driving voltage based on the voltage on a common electrode; and a data driving voltage transmitting module configured for transmitting the data driving voltage to each pixel electrode of pixel units of the display panel.

In the display panel driving device of the present invention, the data driving voltage generating module sets the data driving voltage as the voltage of the common electrode.

In the display panel driving device of the present invention, the data driving voltage generating module sets the data driving voltage to a first driving voltage during a (2n+1)th vertical blanking interval, the data driving voltage generating module sets the data driving voltage to a second driving voltage during a (2n)th vertical blanking interval, the first driving voltage is greater than the voltage of the common electrode, and the second driving voltage is less than the voltage of the common electrode.

In the display panel driving device of the present invention, the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

In the display panel driving device of the present invention, the voltage of the common electrode is constant.

As can be seen from above technical schemes, the display panel driving method and display panel driving device provided in the present invention, during the vertical blanking interval, a scan driving voltage and a data driving voltage are provided to the display panel such that there is no voltage difference generated between the common electrode and the pixel electrode of the display panel. The residual ions will not move toward the pixel electrode or the common electrode, and therefore residual direct current will not occur. This can attenuate or eliminate the image-retention phenomenon on the display panel.

### BRIEF DESCRIPTION OF THE DRAWINGS

The technical schemes and other beneficial effects will be more apparent with reference to the detailed descriptions of the embodiments of the present invention below in accompanying with the drawings,

FIG. 1 is a flow chart of a display panel driving method in accordance with a first preferred embodiment of the present invention.

FIG. 2 is a timing chart of a scan driving voltage in a display panel driving method in accordance with the present invention.

FIG. 3 is a timing chart of a data driving voltage in the display panel driving method in accordance with a first preferred embodiment of the present invention.

FIG. 4 is a flow chart of a display panel driving method in accordance with a second preferred embodiment of the present invention.

FIG. 5 is a timing chart of a data driving voltage in the display panel driving method in accordance with the second preferred embodiment of the present invention.

FIG. 6 is a schematic diagram showing an array substrate in accordance with a display panel of a preferred embodiment of the present invention.

FIG. 7 is a schematic structural diagram showing a display panel driving device in accordance with a first preferred embodiment of the present invention.

FIG. 8 is a schematic structural diagram showing a display panel driving device in accordance with a second preferred embodiment of the present invention.

### DETAILED DESCRIPTION OF THE DISCLOSURE

To make the objectives, technical schemes, and advantages of the present invention more clear and specific, the present invention will be described in further detail below with reference to the embodiments in accompanying with the appending drawings.

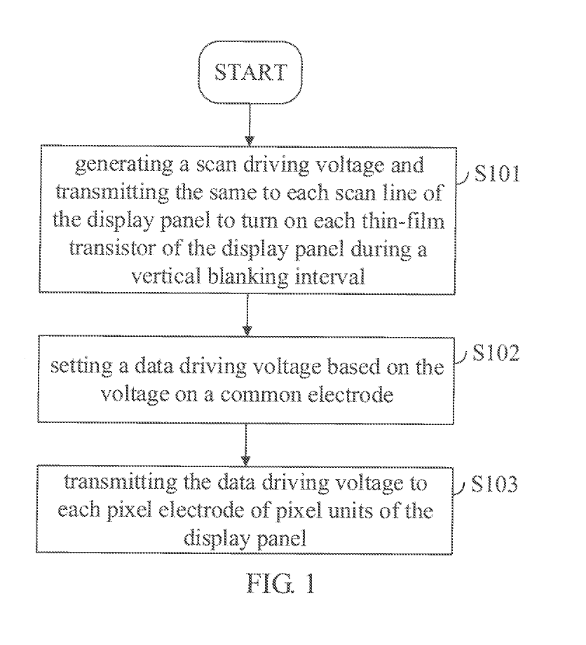

Please refer to FIG. 1, which is a low chart of a display panel driving method in accordance with a first preferred embodiment of the present invention.

The display panel driving method provided in the first preferred embodiment of the present invention comprises the following steps.

In Step S101, a scan driving voltage is generated and is transmitted to each scan line of the display panel to turn on each thin-film transistor of the display panel during a vertical blanking interval.

In Step S102, a data driving voltage is set based on the voltage on a common electrode.

In Step S103, the data driving voltage is transmitted to each pixel electrode of pixel units of the display panel.

Specifically, there mainly has three types of voltages in the display panel driving method of the present invention, that is, the scan driving voltage, the data driving voltage, and the voltage of the common electrode. The scan driving voltage is configured to control the thin-film transistor in the pixel unit on and off. The data driving voltage is configured to drive a source electrode of the thin-film transistor in the pixel unit. The data driving voltage is transmitted to the pixel electrode via the source electrode and a drain electrode. The display panel mainly includes an array substrate and a color filter substrate disposed opposite to each other, and also include a liquid crystal layer disposed between the two substrates. Both of the array substrate and the color filter substrate have common electrodes disposed thereon and the common electrodes are electrically connected to each other. The common electrode on the array substrate is configured to form a storage capacitor in accompanying with the pixel electrode. The common electrode on the color filter substrate is configured to form a liquid capacitor in accompanying with the pixel electrode. The voltage on the common electrode is provided by a common electrode voltage module of the display panel. The common electrode voltage module provides the common electrode voltage during the display panel displays images. The common electrode voltage is constant.

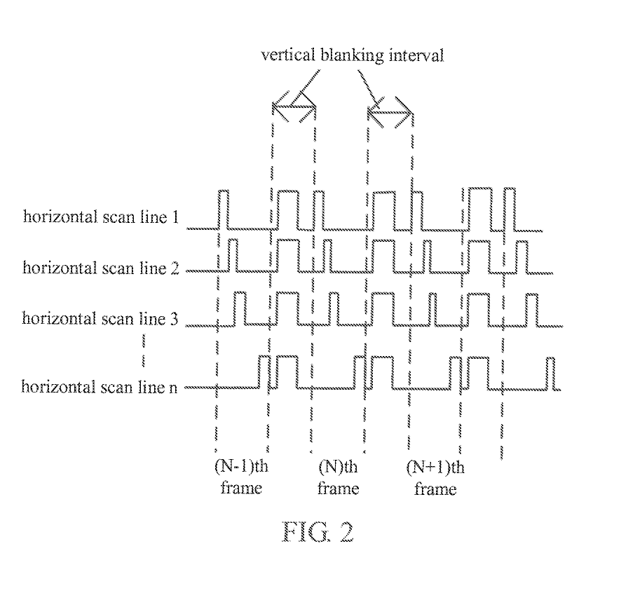

In Step S101, please refer to FIG. 2, which is a timing chart of a scan driving voltage in a display panel driving method in accordance with the present invention.

It can be seen that there are n rows of scan lines on the display panel, and when the scan lines are scanned row by row, the scan driving voltage is sequentially provided to the horizontal scan line 1, the horizontal scan line 2, the horizontal scan line 3, and the horizontal scan line n from top to bottom, thereby carrying out the scanning for a frame of image. A period spanned from the time turning on the thin-film transistor corresponding to the first scan line to the time turning off the thin-film transistor corresponding to the last scan line is called a frame period. Specifically; the voltage on the common electrode is a constant voltage value, which is not varied as the image frames alternate. However, there exists a vertical blanking interval, that is, a period spanned from the time turning off the thin-film transistor corresponding to the last scan line of a previous frame to the time turning on the thin-film transistor corresponding to the fast scan line of a current frame. For example, the time period between the (N−1)th frame and the Nth frame is a vertical blanking interval as well as the time period between the Nth frame and the (N+1)th frame is a vertical blanking interval as shown in FIG. 2. Meanwhile, during the vertical blanking interval, a scan driving voltage is generated and is transmitted to the horizontal scan line 1, the horizontal scan line 2, the horizontal scan line 3, . . . , and the horizontal scan line n, the horizontal scan line 1, the horizontal scan line 2, the horizontal scan line 3, . . . , and the horizontal scan line n are electrically connected to gate electrodes of the thin-film transistors of the pixel units of the respective rows, respectively, and the scan driving voltage is transmitted to each gate electrode of the thin-film transistors of the pixel units via the horizontal scan line 1, the horizontal scan line 2, the horizontal scan line 3, . . . , and the horizontal scan line n to turn on each thin-film transistor of the pixel units. In this way, the data driving voltage can he transmitted to the pixel electrodes of the respective pixel units via source electrodes and drain electrodes of the thin-film transistors.

Specifically, in the vertical blanking interval, the acting time of the scan driving voltage is less than the duration of the vertical blanking interval.

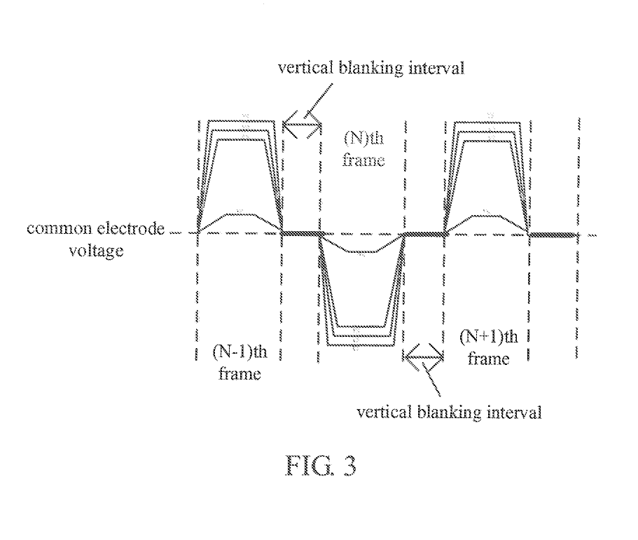

In Step S102, referring to FIG. 3, a data driving voltage is set based on the voltage on a common electrode, Preferably, during the vertical blanking interval, the data driving voltage is set as the voltage of the common electrode.

Specifically, the acting time of the data driving voltage is less than the duration of the vertical blanking interval.

In Step S103, the data driving voltage is transmitted to each pixel electrode of pixel units of the display panel. Specifically, in the embodiment of the present invention, during all the vertical blanking intervals, a data voltage is generated and is transmitted to the pixel electrodes of the respective pixel units of the display panel. Since the data voltage is set as the voltage on the common electrode, there is no voltage difference generated between the pixel electrode and the common electrode. In such a manner, during the vertical blanking interval, charge balance is carried out in a storage capacitor formed between the common electrode and the pixel electrode of the pixel unit of the display panel such that the ions on the display panel will not be turned toward the pixel electrode or the common electrode, and will not be induced to cause residual direct current. In such a way, image-retention phenomenon will not occur.

Further, during the (N−1)th frame, the Nth frame, and the (N+1)th frame, the data voltage can be V1, V2, V3, . . . , Vn, where V1, V2, V3, . . . , Vn are different gray level voltages of the display panel. The data driving voltages of the (N−1)th frame and the Nth frame are switched between positive polarity and negative polarity with respect to the voltage on the common electrode; and the data driving voltages of the Nth frame and the (N+1)th frame are switched between positive polarity and negative polarity with respect to the voltage on the common electrode. This can further prevent the display panel from polarization, causing the image-retention phenomenon.

In the display panel driving method in accordance with the present invention, during the vertical blanking interval, a scan driving voltage and a data driving voltage are provided to the display panel such that there is no voltage difference generated between the common electrode and the pixel electrode of the display panel. The residual ions will not move toward the pixel electrode or the common electrode, and therefore residual direct current will not occur. This can attenuate or eliminate the image-retention phenomenon on the display panel.

The present invention further provides a second preferred embodiment of the display panel driving method. The differences between the second preferred embodiment and the first preferred embodiment are that in the second preferred embodiment, the data driving voltage is set to a first driving voltage during a (2n+1)th vertical blanking interval, the data driving voltage is set to a second driving voltage during a (2n)th vertical blanking interval, the first driving voltage is greater than the voltage of the common electrode, and the second driving voltage is less than the voltage of the common electrode. Likewise, this can make the display panel not cause the image-retention phenomenon.

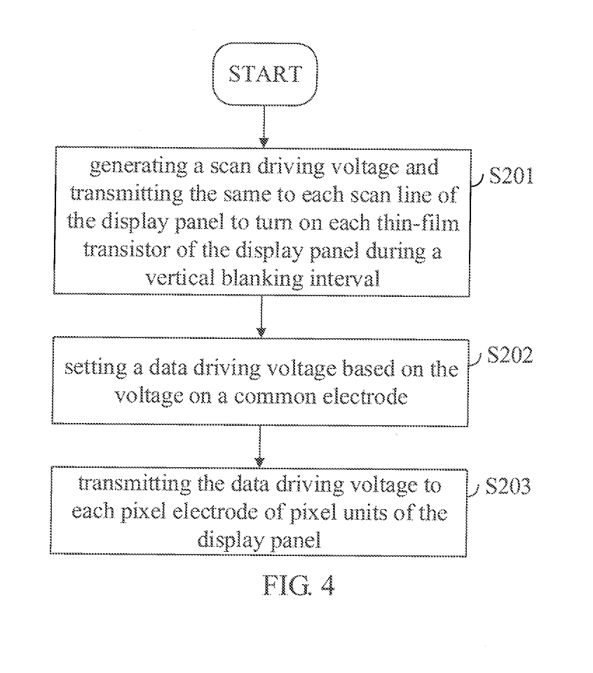

Please refer to FIG. 4, which is a flow chart of a display panel driving method in accordance with a second preferred embodiment of the present invention.

The display panel driving method provided in the second preferred embodiment of the present invention comprises the following steps.

In Step S201, a scan driving voltage is generated and is transmitted to each scan line of the display panel to turn on each thin-film transistor of the display panel during a vertical blanking interval.

In Step S202, a data driving voltage is set based on the voltage on a common electrode.

In Step S203, the data driving voltage is transmitted to each pixel electrode of pixel units of the display panel.

Specifically, there mainly has three types of voltages in the display panel driving method of the present invention, that is, the scan driving voltage, the data driving voltage, and the voltage of the common electrode. The scan driving voltage is configured to control the thin-film transistor in the pixel unit on and off. The data driving voltage is configured to drive a source electrode of the thin-film transistor in the pixel unit. The data driving voltage is transmitted to the pixel electrode via the source electrode and a drain electrode. The display panel mainly includes an array substrate and a color filter substrate disposed opposite to each other, and also includes a liquid crystal layer disposed between the two substrates. Both of the array substrate and the color filter substrate have common electrodes disposed thereon and the common electrodes are electrically connected to each other. The common electrode on the array substrate is configured to form a storage capacitor in accompanying with the pixel electrode. The common electrode on the color filter substrate is configured to form a liquid capacitor in accompanying with the pixel electrode. The voltage on the common electrode is provided by a common electrode voltage module of the display panel. The common electrode voltage module provides the common electrode voltage during the display panel displays images. The common electrode voltage is constant.

In Step S201, please refer to FIG. 2, which is a timing chart of a scan driving voltage in a display panel driving method in accordance with the present invention.

It can be seen that there are ii rows of scan lines on the display panel, and when the scan lines are scanned row by row, the scan driving voltage is sequentially provided to the horizontal scan line 1, the horizontal scan line 2, the horizontal scan line 3, . . . , and the horizontal scan line n from top to bottom, thereby carrying out the scanning for a frame of image. A period spanned from the time turning on the thin-film transistor corresponding to the first scan line to the time turning off the thin-film transistor corresponding to the last scan line is called a frame period. Specifically, the voltage on the common electrode is a constant voltage value, which is not varied a.s the image frames alternate. However, there exists a vertical blanking interval, that is, a period spanned from the time turning off the thin-film transistor corresponding to the last scan line of a previous frame to the time turning on the thin-film transistor corresponding to the fast scan line of a current frame. For example, the time period between the (N−1)th frame and the Nth frame is a vertical blanking interval as well as the time period between the Nth frame and the (N+1)th frame is a vertical blanking interval as shown in FIG. 2. Meanwhile, during the vertical blanking interval, a scan driving voltage is generated and is transmitted to the horizontal scan line 1, the horizontal scan line 2, the horizontal scan line 3, . . . , and the horizontal scan line n, the horizontal scan line 1, the horizontal scan line 2, the horizontal scan line 3, . . . , and the horizontal scan line n are electrically connected to gate electrodes of the thin-film transistors of the pixel units of the respective rows, respectively, and the scan driving voltage is transmitted to each gate electrode of the thin-film transistors of the pixel units via the horizontal scan line 1, the horizontal scan line 2, the horizontal scan line 3, . . . , and the horizontal scan line n to turn on each thin-film transistor of the pixel units. In this way, the data driving voltage can be transmitted to the pixel electrodes of the respective pixel units via source electrodes and drain electrodes of the thin-film transistors.

Specifically, in the vertical blanking interval, the acting time of the scan driving voltage is less than the duration of the vertical blanking interval.

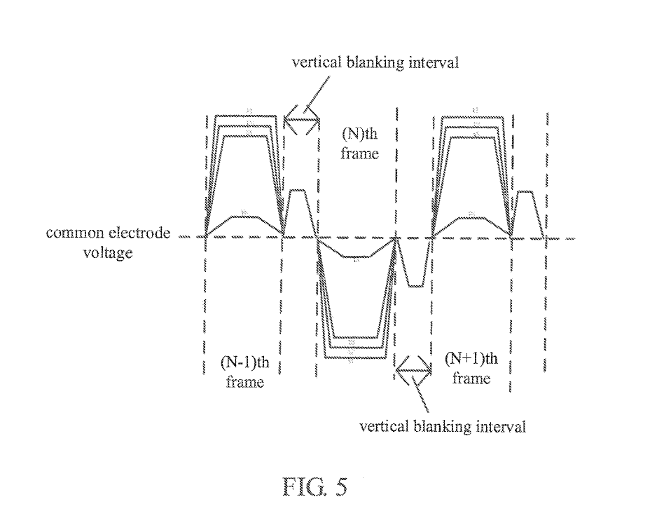

Please refer to FIG. 5, which is a timing chart of a data driving voltage in the display panel driving method in accordance with the second preferred embodiment of the present invention.

In Step S202, referring to FIG. 5, a data driving voltage is set based on the voltage on a common electrode. Preferably, the data driving voltage is set to a first driving voltage during a (2n+1)th vertical blanking interval and the data driving voltage is set to a second driving voltage during a (2n)th vertical blanking interval. For example, the data driving voltage is set to the first driving voltage during the alternating period between the (N−1)th frame and the Nth frame and the data driving voltage is set to the second driving voltage during the alternating period between the Nth frame and the (N+1)th frame.

Preferably, the data driving voltage can be set to the first driving voltage during the (2n)th vertical blanking interval and the data driving voltage can be set to the second driving voltage during the (2n+1)th vertical blanking interval.

The first driving voltage is greater than the voltage of the common electrode. The second driving voltage is less than the voltage of the common electrode.

Specifically, the acting time of the data driving voltage is less than the duration of the vertical blanking interval.

In Step S203, the data driving voltage is transmitted to each pixel electrode of pixel units of the display panel. Specifically, in the embodiment of the present invention, during the (2n−1)th vertical blanking interval, a first driving voltage is generated and is transmitted to the pixel electrodes of the respective pixel units of the display panel. Therethre, a first voltage difference is generated between the pixel electrode and the common electrode. The first voltage difference is equal to a voltage resulted from subtracting the voltage on the common electrode from the voltage on the pixel electrode. Further, in the embodiment of the present it vention, during the (2n)th vertical blanking interval, a second driving voltage is generated and is transmitted to the pixel electrodes of the respective pixel units of the display panel. Therefore, a second voltage difference is generated between the pixel electrode and the common electrode. The second voltage difference is equal to a voltage resulted from subtracting the voltage on the common electrode from the voltage on the pixel electrode.

Preferably, in the embodiment of the present invention, during the (2n)th vertical blanking interval, a first driving voltage is generated and is transmitted to the pixel electrodes of the respective pixel units of the display panel. Therefore, a first voltage difference is generated between the pixel electrode and the common electrode. The first voltage difference is equal to a voltage resulted from subtracting the voltage on the common electrode from the voltage on the pixel electrode. Further, in the embodiment of the present invention, during the (2n+1)th vertical blanking interval, a second driving voltage is generated and is transmitted to the pixel electrodes of the respective pixel units of the display panel. Therefore, a second voltage difference is generated between the pixel electrode and the common electrode. The second voltage difference is equal to a voltage resulted from subtracting the voltage on the common electrode from the voltage on the pixel electrode.

Further, the sum of the first voltage difference and the second voltage difference is zero. Specifically, when the residual ions on the display panel are positive ions, the positive ions may move toward the pixel electrode during the (2n)th vertical blanking interval due to the second voltage difference existing between the pixel electrode and the common electrode, and the positive ions may move toward the common electrode during the (2n+1)th vertical blanking interval due to the first voltage difference between the pixel electrode and the common electrode. After the (2n)th vertical blanking interval and the (2n+1)th vertical blanking interval, charge balance is carried out in a storage capacitor formed between the common electrode and the pixel electrode of the pixel unit of the display panel. Positive ions will not be turned toward the pixel electrode and the common electrode, and ions will not be induced to cause residual direct current. In such a way, image-retention phenomenon will not occur.

Preferably, when the residual ions on the display panel are positive ions, the positive ions may move toward the pixel electrode during the (2n+1)th vertical blanking interval due to the second voltage difference existing between the pixel electrode and the common electrode, and the positive ions may move toward the common electrode during the (2n)th vertical blanking interval due to the first voltage difference between the pixel electrode and the common electrode. After the (2n)th vertical blanking interval and the (2n+1)th vertical blanking interval, charge balance is carried out in a storage capacitor formed between the common electrode and the pixel electrode of the pixel unit of the display panel. Positive ions will not be turned toward the pixel electrode and the common electrode, and ions will not be induced to cause residual direct current. In such a way, image-retention phenomenon will not occur.

During the (N−1)th frame, the Nth frame, and the (N+1)th frame, the data voltage can be V1, V2, V3, . . . , Vn, where V1, V2, V3, . . . , Vn are different gray level voltages of the display panel. The data driving voltages of the (N−1)th frame and the Nth frame are switched between positive polarity and negative polarity with respect to the voltage on the common electrode, and the data driving voltages of the Nth frame and the (N+1)th frame are switched between positive polarity and negative polarity with respect to the voltage on the common electrode. This can further prevent the display panel from polarization, causing the image-retention phenomenon.

In the display panel driving method provided in the embodiment of the present invention, during the vertical blanking interval, a scan driving voltage and a data driving voltage are provided to the display panel such that there is no voltage difference generated between the common electrode and the pixel electrode of the display panel after the (2n)th vertical blanking interval and the (2n+1)th vertical blanking interval. The residual ions will not move toward the pixel electrode or the common electrode, and therefore residual direct current will not occur. This can attenuate or eliminate the image-retention phenomenon on the display panel,

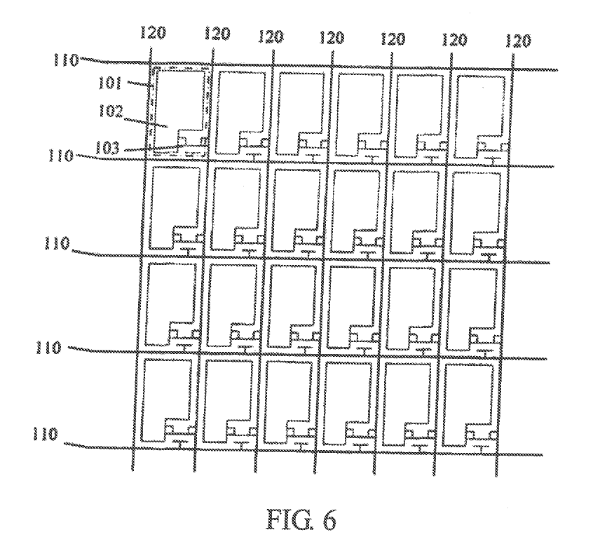

Please refer to FIG. 6, which is a schematic diagram showing an array substrate in accordance with a display panel of a preferred embodiment of the present invention.

The display panel of the present invention mainly includes an array substrate and a color filter substrate disposed opposite to each other, and also include a liquid crystal layer disposed between the two substrates. The liquid crystal layer is formed by liquid crystal molecules.

The array substrate comprises scan lines 110 arranged along a horizontal direction on the substrate and data lines 120 arranged along a vertical direction on the substrate. The scan lines 110 and the data lines 120 are intersected to each other to form pixel units 101. The pixel units 101 comprises pixel electrode 102 and thin-film transistors 103. The gate electrode of the thin-film transistor 103 is electrically connected to the scan line 101, the source electrode is electrically connected to the data line 120, and the drain electrode is electrically connected to the pixel electrode 102. Each scan line 110 is connected to the gate electrodes of the respective thin-film transistors in a corresponding row. Each data line 120 is connected to the source electrodes of the respective thin-film transistors in a corresponding column.

When the display panel works, the scan line 110 is utilized to transmit the scan driving voltage to the respective thin-film transistors 103 in a corresponding row to control turning on or turning off the thin-film transistors 103 row by row. When the thin-film transistors 103 are in a turned-on state, the data driving voltage on the data line will be applied to the pixel electrodes 102 of the pixel units 101 via the source electrodes and the drain electrodes of the thin-film transistors 103.

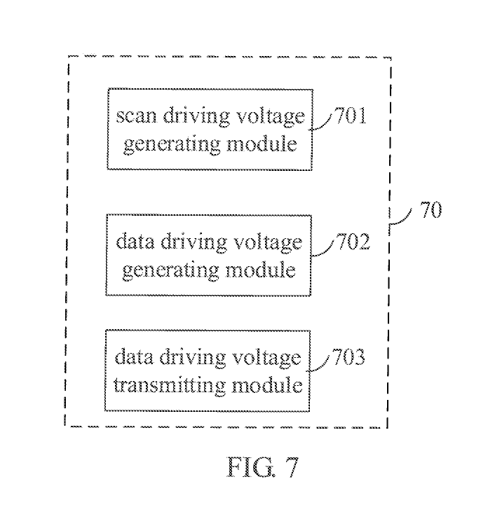

Please refer to FIG. 7, which is a schematic structural diagram showing a display panel driving device in accordance with a first preferred embodiment of the present invention.

The display panel driving device 70 of the present preferred embodiment comprises a scan driving voltage generating module 701, a data driving voltage generating module 702, and a data driving voltage transmitting module 703. The scan driving voltage generating module 701 is configured for generating a scan driving voltage and transmitting the same to each scan line of the display panel to turn on each thin-film transistor of the display panel during a vertical blanking interval; the data driving voltage generating module 702 is configured for setting a data driving voltage based on the voltage on a common electrode; and the data driving voltage transmitting module 703 is configured for transmitting the data driving voltage to each pixel electrode of pixel units of the display panel.

During the vertical blanking interval, the scan driving voltage generating module 701 generates a scan driving voltage and transmits the same to the horizontal scan line 1, the horizontal scan line 2, the horizontal scan line 3, . . . , and the horizontal scan line n, the horizontal scan line 1, the horizontal scan line 2, the horizontal scan line 3, . . . , and the horizontal scan line n are electrically connected to gate electrodes of the thin-film transistors of the pixel units of the respective rows, respectively, and the scan driving voltage is transmitted to each gate electrode of the thin-film transistors of the pixel units via the horizontal scan line 1, the horizontal scan line 2, the horizontal scan line 3, . . . , and the horizontal scan line n to turn on each thin-film transistor of the pixel units. In this way; the data driving voltage can be transmitted to the pixel electrodes of the respective pixel units via source electrodes and drain electrodes of the thin-film transistors.

The data driving voltage generating module 702 sets a data driving voltage based on the voltage on a common electrode. During the vertical blanking interval, the data driving voltage generating module 702 sets the data. driving voltage as the voltage of the common electrode.

The data driving voltage transmitting module 703 transmits the data driving voltage generated by the data driving voltage generating module 702 to each pixel electrode of pixel units of the display panel. Specifically, in the embodiment of the present invention, during all the vertical blanking intervals, a data voltage is generated and is transmitted to the pixel electrodes of the respective pixel units of the display panel. Since the data voltage is set as the voltage .on the common electrode, there is no voltage difference generated between the pixel electrode and the common electrode. In such a manner, during the vertical blanking interval, charge balance is carried out in a storage capacitor formed between the common electrode and the pixel electrode of the pixel unit of the display panel such that the ions on the display panel will not be turned toward the pixel electrode or the common electrode, and will not be induced to cause residual direct current. In such a way, image-retention phenomenon will not occur.

During the (N−1)th frame, the Nth frame, and the (N+1)th frame, the data driving voltage generating module 702 can set the data voltage to be V1, V2, V3, . . . , Vn, where V1, V2, V3, . . . , Vn. are different gray level voltages of the display panel. The data driving voltages of the (N−1)th frame and the Nth frame are switched between positive polarity and negative polarity with respect to the voltage on the common electrode, and the data driving voltages of the Nth frame and the (N+1)th frame are switched between positive polarity and negative polarity with respect to the voltage on the common electrode. This can further prevent the display panel from polarization, causing the image-retention phenomenon.

In the display panel driving device 70 in accordance with the embodiment of the present invention, a scan driving voltage is inputted to the gate electrodes of the respective thin-film transistors on the display panel via the scan lines 110 during the vertical blanking interval, and a data driving voltage is inputted to the pixel electrodes 102 of the respective pixel units 101 on to display panel via the data lines 120. In such a manner, residual direct current caused by ions can be attenuated or eliminated during the vertical blanking interval. In this way, image overlapping will not occur in switching the images and image retention can be easily eliminated.

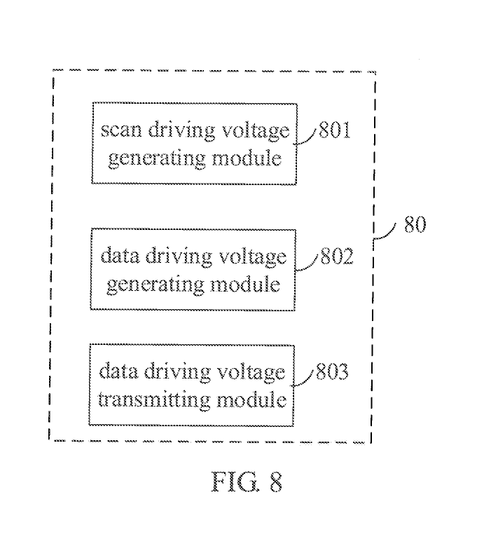

Please refer to FIG. 8, which is a schematic structural diagam showing a display panel driving device in accordance with a second preferred embodiment of the present invention.

The display panel driving device 80 of the present preferred embodiment comprises a scan driving voltage generating module 801, a data driving voltage generating module 802, and a data driving voltage transmitting module 803. The scan driving voltage generating module 801 is configured for generating a scan driving voltage and transmitting the same to each scan line of the display panel to turn on each thin-film transistor of the display panel during a vertical blanking interval; the data driving voltage generating module 802 is configured for setting a data driving voltage based on the voltage on a. common electrode; and the data driving voltage transmitting module 803 is configured for transmitting the data driving voltage to each pixel electrode of pixel units of the display panel.

During the vertical blanking interval, the scan driving voltage generating module 801 generates a scan driving voltage and transmits the same to the horizontal scan line 1, the horizontal scan line 2, the horizontal scan line 3, . . . , and the horizontal scan line n, the horizontal scan line 1, the horizontal scan line 2, the horizontal scan line 3, . . . , and the horizontal scan line n are electrically connected to gate electrodes of the thin-film transistors of the pixel units of the respective rows, respectively, and the scan driving voltage is transmitted to each gate electrode of the thin-film transistors of the pixel units via the horizontal scan line 1, the horizontal scan line 2, the horizontal scan line 3, . . . , and the horizontal scan line n to turn on each thin-film transistor of the pixel units in this way, the data driving voltage can be transmitted to the pixel electrodes of the respective pixel units via source electrodes and drain electrodes of the thin-film transistors.

The data driving voltage generating module 802 sets a data driving voltage based on the voltage on a common electrode. The data driving voltage generating module 802 may set the data driving voltage to the first driving voltage during the (2n+1)th vertical blanking interval and The data driving voltage generating module 802 may set the data driving voltage to the second driving voltage during the (2n)th vertical blanking interval.

Preferably, the data driving voltage generating module 802 may set the data driving voltage to the first driving voltage during the (2n)th vertical blanking interval and The data driving voltage generating module 802 may set the data driving voltage to the second driving voltage during the (2n+1)th vertical blanking interval.

The first driving voltage is greater than the voltage of the common electrode. The second driving voltage is less than the voltage of the common electrode.

The data driving voltage transmitting module 803 transmits the data driving voltage generated by the data driving voltage generating module 802 to each pixel electrode of pixel units of the display panel. Specifically, in the embodiment of the present invention, during the (2n+1)th vertical blanking interval, a first driving voltage is generated and is transmitted to the pixel electrodes of the respective pixel units of the display panel. Therefore, a first voltage difference is generated between the pixel electrode and the common electrode. The first voltage difference is equal to a voltage resulted from subtracting the voltage on the common electrode from the voltage on the pixel electrode. Further, in the embodiment of the present invention, during the (2n)th vertical blanking interval, a second driving voltage is generated and is transmitted to the pixel electrodes of the respective pixel units of the display panel. Therefore, a second voltage difference is generated between the pixel electrode and the common electrode. The second voltage difference is equal to a voltage resulted from subtracting the voltage on the common electrode from the voltage on the pixel electrode.

Preferably, in the embodiment of the present invention, during the (2n)th vertical blanking interval, a first driving voltage is generated and is transmitted to the pixel electrodes of the respective pixel units of the display panel. Therefore, a first voltage difference is generated between the pixel electrode and the common electrode. The first voltage difference is equal to a voltage resulted from subtracting the voltage on the common electrode from the voltage on the pixel electrode. Further, in the embodiment of the present invention, during the (2n+1)th vertical blanking interval, a second driving voltage is generated and is transmitted to the pixel electrodes of the respective pixel units of the display panel. Therefore, a second voltage difference is generated between the pixel electrode and the common electrode. The second voltage difference is equal to a voltage resulted from subtracting the voltage on the common electrode from the voltage on the pixel electrode.

Further, the sum of the first voltage difference and the second voltage difference is zero. Specifically, when the residual ions on the display panel are positive ions, the positive ions may move toward the pixel electrode during the (2n)th vertical blanking interval due to the second voltage difference existing between the pixel electrode and the common electrode, and the positive ions may move toward the common electrode during the (2n+1)th vertical blanking interval due to the first voltage difference between the pixel electrode and the common electrode. After the (2n)th vertical blanking interval and the (2n+1)th vertical blanking interval, charge balance is carried out in a storage capacitor formed between the common electrode and the pixel electrode of the pixel unit of the display panel. Positive ions will not be turned toward the pixel electrode and the common electrode, and ions will not be induced to cause residual direct current. In such a way, image-retention phenomenon will not occur.

Preferably, when the residual ions on the display panel are positive ions, the positive ions may move toward the pixel electrode during the (2n+1)th vertical blanking interval due to the second voltage difference existing between the pixel electrode and the common electrode, and the positive ions may move toward the common electrode during the (2n)th vertical blanking interval due to the first voltage difference between the pixel electrode and the common electrode. After the (2n)th vertical blanking interval and the (2n+1)th vertical blanking interval, charge balance is carried out in a storage capacitor formed between the common electrode and the pixel electrode of the pixel unit of the display panel. Positive ions will not be turned toward the pixel electrode and the common electrode, and ions will not be induced to cause residual direct current. In such a way, image-retention phenomenon will not occur.

During the (N−1)th frame, the Nth frame, and the (N+1)th frame, the data driving voltage generating module 802 can set the data voltage to be V1, V2, V3, . . . , Vn, where V1, V2, V3, . . . , Vn are different gray level voltages of the display panel. The data driving voltages of the (N−1)th frame and. the Nth frame are switched between positive polarity and negative polarity with respect to the voltage on the common electrode, and the data driving voltages of the Nth frame and the (N+1)th frame are switched between positive polarity and negative polarity with respect to the voltage on the common electrode. This can further prevent the display panel from polarization, causing the image-retention phenomenon.

In the display panel driving device 80 in accordance with the embodiment of the present invention, a scan driving voltage is inputted to the gate electrodes of the respective thin-film transistors on the display panel via the scan lines 110 during the vertical blanking interval, and a data driving voltage is inputted to the pixel electrodes 102 of the respective pixel units 101 on to display panel via the data lines 120. In such a manner, residual direct current caused by ions can be attenuated or eliminated during the vertical blanking interval. In this way, image overlapping will not occur in switching the images and image retention can be easily eliminated.

In the display panel driving method and display panel driving device in accordance with the present invention, during the vertical blanking interval, a scan. driving voltage and a data driving voltage are provided to the display panel such that there is no voltage difference generated between the common electrode and the pixel electrode of the display panel. The residual ions will not move toward the pixel electrode or the common electrode, and therefbre residual direct current will not occur. This can attenuate or eliminate the image-retention phenomenon on the display panel.

Above descriptions are preferred enibodiments of the present invention. It should be noted that various modifications and alterations can be made by persons skilled in this art without departing from the principles of the present invention, and that all modifications and alterations are within the scope of the present invention.

What is claimed is:

1. A display panel driving method, comprising the steps of:
generating a scan driving voltage and transmitting the same to each scan line of the display panel to turn on each thin-film transistor of the display panel during a vertical blanking interval;
setting a data driving voltage based on the voltage on a common electrode, in which the data driving voltage is set as the voltage of the common electrode and the voltage of the common electrode is constant; and
transmitting the data driving voltage to each pixel electrode of pixel units of the display panel.

2. The display panel driving method according to claim 1, wherein in the step of setting the data driving voltage based on the voltage on the common electrode, the data driving voltage is set to a first driving voltage during a (2n−1)th vertical blanking interval, the data driving voltage is set to a second driving voltage during a (2n)th vertical blanking interval, the first driving voltage is greater than the voltage of the common electrode, and the second driving voltage is less than the voltage of the common electrode.

3. The display panel driving method according to claim 2, wherein the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

4. The display panel driving method according to claim 1, wherein in the step of setting the data driving voltage based on the voltage on the common electrode, the data driving voltage is set to a first driving voltage during a (2n)th vertical blanking interval, the data driving voltage is set to a second driving voltage during a (2n+1)th vertical blanking interval, the first driving voltage is greater than the voltage of the common electrode, and the second driving voltage is less than the voltage of the common electrode.

5. The display panel driving method according to claim 4, wherein the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

6. A display panel driving method, comprising the steps of:
generating a scan driving voltage and transmitting the same to each scan line of the display panel to turn on each thin-film transistor of the display panel during a vertical blanking interval;
setting a data driving voltage based on the voltage on a common electrode; and
transmitting the data driving voltage to each pixel electrode of pixel units of the display panel.

7. The display panel driving method according to claim 6, wherein in the step of setting the data driving voltage based on the voltage on the common electrode, the data driving voltage is set as the voltage of the common electrode.

8. The display panel driving method according to claim 6, wherein in the step of setting the data driving voltage based on the voltage on the common electrode, the data driving voltage is set to a first driving voltage during a (2n+1)th vertical blanking interval, the data driving voltage is set to a second driving voltage during a (2n)th vertical blanking interval, the first driving voltage is greater than the voltage of the common electrode, and the second driving voltage is less than the voltage of the common electrode.

9. The display panel driving method according to claim 8, wherein the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

10. The display panel driving method accorshng to claim 6, wherein the voltage of the common electrode is constant.

11. A display panel driving device, comprising;
a scan driving voltage generating module configured for generating a scan driving voltage and transmitting the same to each scan line of the display panel to turn on each thin-film transistor of the display panel during a vertical blanking interval;
a data driving voltage generating module configured for setting a data driving voltage based on the voltage on a common electrode; and
a data driving voltage transmitting module configured for transmitting the data driving voltage to each pixel electrode of pixel units of the display panel.

12. The display panel driving device according to claim 11, wherein the data driving voltage generating module sets the data driving voltage as the voltage of the common electrode.

13. The display panel driving device according to claim 12, wherein the data driving voltage generating module sets the data driving voltage to a first driving voltage during a (2n+1)th vertical blanking interval, the data driving voltage generating module sets the data driving voltage to a second driving voltage during a (2n)th vertical blanking interval, the first driving voltage is greater than the voltage of the common electrode, and the second driving voltage is less than the voltage of the common electrode.

14. The display panel driving device according to claim 13, wherein the voltage difference between the first driving voltage and the voltage of the common electrode is a first voltage difference, the voltage difference between the second driving voltage and the voltage of the common electrode is a second voltage difference, and the sum of the first voltage difference and the second voltage difference is zero.

15. The display panel driving device according to claim 14, wherein the voltage of the common electrode is constant.
